(19) United States
(12) Patent Application Publication
(10) Pub. No.: US 2014/0110833 A1
(43) Pub. Date: Apr. 24, 2014

(54) POWER MODULE PACKAGE

(71) Applicant: SAMSUNG ELECTRO-MECHANICS CO., LTD., Suwon (KR)

(72) Inventors: Do Jae Yoo, Suwon (KR); Si Joong Yang, Suwon (KR)

(73) Assignee: SAMSUNG ELECTRO-MECHANICS CO., LTD., Suwon (KR)

(21) Appl. No.: 14/060,456

(22) Filed: Oct. 22, 2013

(30) Foreign Application Priority Data
Oct. 24, 2012 (KR) 10-2012-0118521

(51) Int. Cl. H01L 23/00

(52) U.S. Cl. CPC H01L 24/67
USPC 257/697

(57) ABSTRACT

Disclosed herein is a power module package. The power module package includes a substrate having one surface formed with a circuit pattern including a chip mounting pad and an external connection pad and the other surface; a semiconductor chip mounted on the chip mounting pad; and an external connection terminal having one terminal and the other terminal, the one terminal being connected to the external connection pad and the other terminal protruding to the outside, in which the external connection pad and the external connection terminal are bonded to each other by welding.

### CROSS REFERENCE TO RELATED APPLICATION

This application claims the benefit of Korean Patent Application No. 10-2012-0118521, filed on Oct. 24, 2012, entitled “Power Module Package” which is hereby incorporated by reference in its entirety into this application.

### BACKGROUND OF THE INVENTION

1. Technical Field

The present invention relates to a power module package.

2. Description of the Related Art

With the recent development of electronic industries for power, a demand for small, high-density electronic products has increased. Therefore, in addition to a method for reducing a size of electronic devices, a method for installing as many devices and conducting wires as possible within a defined space becomes an important problem in designing a power module package.

Meanwhile, a structure of the power module package according to the prior art is disclosed in U.S. Pat. No. 5,920,119.

### SUMMARY OF THE INVENTION

The present invention has been made in an effort to provide a power module package capable of facilitating manufacturing and saving process costs by simplifying the process.

Further, the present invention has been made in an effort to provide a power module package capable of reducing a bonded area of external connection terminals and improving bonding strength thereof.

In addition, the present invention has been made in an effort to provide a power module package for reducing a risk of the occurrence of cracks at a bonding interface between external connection terminals.

According to a preferred embodiment of the present invention, there is provided a power module package, including: a substrate having one surface formed with a circuit pattern including a chip mounting pad and an external connection pad and the other surface; a semiconductor chip mounted on the chip mounting pad; and an external connection terminal having one terminal and the other terminal, the one terminal being connected to the external connection pad and the other terminal protruding to the outside, in which the external connection pad and the external connection terminal are bonded to each other by welding.

The welding may be any one selected from ultrasonic welding, laser welding, and resistance welding.

One terminal of the external connection terminal may be formed with a protrusion and the substrate may be formed with an insertion groove corresponding to the protrusion.

The substrate may include: a metal plate; an insulating layer formed on the metal plate; and a circuit pattern formed on the insulating layer and including a chip mounting pad and an external connection pad, in which the insertion groove is formed to a predetermined depth in a thickness direction of the insulating layer by penetrating through the external connection pad.

The external connection terminal may have a pin shape.

The external connection terminal may be formed so that a diameter of the one terminal is larger than that of the other terminal

The external connection terminal may have a diameter which decreases from the one terminal toward the other terminal

The power module package may further include: a case formed on the substrate and covering one surface of the substrate, a semiconductor chip, and a portion of the external connection terminal and exposing the other terminal of the external connection terminal to the outside.

The power module package may further include: a sealing member formed within the case to enclose one surface of the substrate, the semiconductor chip, and a portion of the external connection terminal

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view illustrating a structure of a power module package according to a preferred embodiment of the present invention; and

FIG. 2 is a cross-sectional view illustrating a structure in which a protrusion is formed on one end of an external connection terminal in the power module package of FIG. 1.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the accompanying drawings.

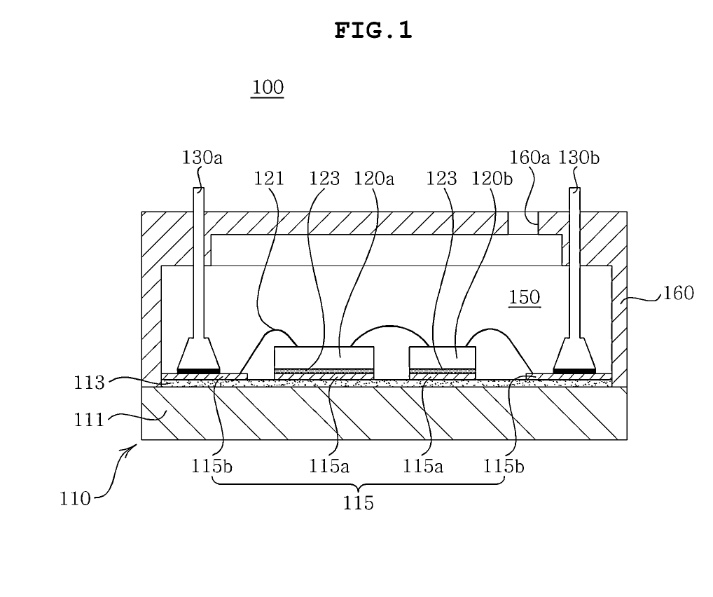

FIG. 1 is a cross-sectional view illustrating a structure of a power module package according to a preferred embodiment of the present invention.

Referring to FIG. 1, a power module package 100 according to the preferred embodiment of the present invention may include a substrate 110, a circuit pattern 115 which is formed on one surface of the substrate 110 and includes a chip mounting pad 115a, and an external connection pad 115b, semiconductor chips 120a and 120b mounted on the chip mounting pad 115a, and external connection terminals 130a and 130b having one terminal and the other terminal, in which the one terminal is bonded to the external connection pad 115b and the other terminal protrudes to the outside.

According to the preferred embodiment of the present invention, the substrate 110 may be configured of a metal plate 111, an insulating layer 113 formed on one surface of the metal plate 111, and a the circuit pattern 115 formed on the insulating layer 113.

In this configuration, the metal plate 111 may be made of inexpensive metal materials which may be easily obtained and aluminum (Al) or aluminum alloy (Al alloy) having high thermal conductivity, but is not limited thereto. Therefore, any metal having high thermal conductivity may be used.

According to the preferred embodiment of the present invention, the substrate 110 has one surface and the other surface. In this case, referring to FIG. 1, the one surface may mean a surface on which the semiconductor chips 120a and 120b are mounted, that is, a surface on which the circuit pattern 115 is formed and the other surface may mean a surface opposite thereto, that is, an exposed surface of the metal plate 111.

As described above, the preferred embodiment of the present invention illustrates the substrate 110 configured of the metal plate 111, the insulating layer 113, and the circuit pattern 115, but is not particularly limited thereto. For example, an example of the substrate 110 may include a metal substrate having an anodizing layer, a printed circuit board (PCB), a ceramic substrate, a direct bonded copper (DBC) substrate, and the like.

Further, according to the preferred embodiment of the present invention, as illustrated in FIG. 1, the circuit pattern 115 may include the chip mounting pad 115a and the external connection pad 115b, but is not particularly limited thereto.

According to the preferred embodiment of the present invention, the semiconductor chips 120a and 120b mounted on the chip mounting pad 115b may be a power device, but is not particularly limited thereto.

In this case, the power device may include a silicon controlled rectifier (SCR), a power transistor, an insulated gate bipolar transistor (IGBT), a MOS transistor, a power rectifier, a power regulator, an inverter, a converter, or a high power semiconductor chip or diode including a combination thereof.

Further, according to the preferred embodiment of the present invention, a bonding layer 123 may also be formed between the semiconductor chips 120a and 120b and the chip mounting pad 115a. The bonding layer 123 may be made of solder or conductive epoxy having relatively high thermal conductivity in order to effectively radiate heat, but is not particularly limited thereto.

Further, according to the preferred embodiment of the present invention, the semiconductor chips 120a and 120b, the substrate 110, and the external connection terminals 130a and 130b may be electrically connected with each other by a wire 121, but are not particularly thereto.

In this case, a wire bonding process may be performed by ball bonding, wedge bonding, and stitch bonding well known in the art, but is not particularly thereto.

Herein, as the wire aluminum (Al), gold (Au), copper (Cu), and the like, may be used, but the preferred embodiment of the present invention is not particularly thereto. In general, as the wire applying high rated voltage to the semiconductor chips 120a and 120b which are the power device, the wire made of aluminum (Al) may be used. Meanwhile, a thick wire needs to be used to withstand a high voltage. Therefore, using aluminum (Al) is more effective in terms of reducing costs than using gold (Au) or copper (Cu).

According to the preferred embodiment of the present invention, the external connection terminals 130a and 130b is configured to be electrically connected to an external driving IC to drive the semiconductor chips 120a and 120b mounted on the chip mounting pad 115a. Meanwhile, according to the preferred embodiment of the present invention, as illustrated in FIG. 1, the external connection terminals 130a and 130b may be formed in a pin shape, but are not particularly thereto.

Further, according to the preferred embodiment of the present invention, the external connection terminals 130a and 130b have one terminal and the other terminal, in which the one terminal may be bonded to the external connection pad 115b and the other end may protrude to the outside.

In this case, the external connection pad 115b and the external connection terminals 130a and 130b may be directly bonded to each other by a welding method which is a metal bonding method.

According to the preferred embodiment of the present invention, as the welding method an ultrasonic welding method, a laser welding method, a resistance welding method, and the like, may be used, but the preferred embodiment of the present invention is not particularly limited thereto and any welding method for known metal bonding may be used

In recent, to manufacture the power module package having a compact size, the pin-shaped external connection terminal is used.

The pin-shaped external connection terminal is inserted into a fastening member, such as a socket attached on the substrate, and thus may be electrically and mechanically connected to the substrate. In implementing the above structure, since a process of attaching a separate fastening member, such as a socket, on the substrate is additionally required, the process may be complicated and the process costs may increase.

In detail, the socket may be attached on the substrate by soldering. Therefore, processes of solder paste print, socket arrangement, reflow, and the like, are additionally required, such that the number of processes and the process costs may increase.

Further, as described above, the solder is spread due to the attachment of the socket on the substrate by the soldering, such that a clearance from the wire bonding may be restricted and a position and a height of a socket mounting surface may not easily secured.

Further, a risk of the occurrence of cracks at the soldering interface increases, and thus the reliability of products may reduce.

On the other hand, since the external connection terminals 130a and 130b are directly bonded to the external connection pad 115b by the welding method which is the metal bonding method, the power module package 100 according to the preferred embodiment of the present invention does not require the process of attaching the socket, which is the separate fastening member, on the substrate to simplify the structure and the process and does not require the use of the socket to save the process costs, as compared with the structure of the prior art.

Further, the power module package 100 according to the preferred embodiment of the present invention does not perform the soldering process at the time of connecting to the external connection terminal, thereby preventing several problems which may occur at the time of the soldering, for example, preventing the bonded position of the external connection terminals from separating, the cracks from occurring at the soldering interface, and the like.

Further, as illustrated in FIG. 1, the external connection terminals 130a and 130b of the power module package 100 according to the preferred embodiment of the present invention is configured of one terminal bonded to the external connection pad 115b and the other terminal protruding to the outside and according to the preferred embodiment of the present invention, the external connection terminals 130a and 130b may be formed so that a diameter of one terminal is larger than that of the other terminal, but is not particularly thereto.

This is to maintain a more stable contact state until the bonding completes, when the external connection terminals 130a and 130b are bonded on the external connection pad 115b.

In this case, as illustrated in FIG. 1, the overall shape of the external connection terminals 130a and 130b may be a shape in which a long bar shape in a rectangular shape is connected to a trapezoidal pin, but is not particularly thereto. Although not illustrated, the external connection terminals 130a and 130b may be also formed in a trapezoidal shape of which the diameter increases from the other terminal of the external connection terminals 130a and 130b toward one end thereof.

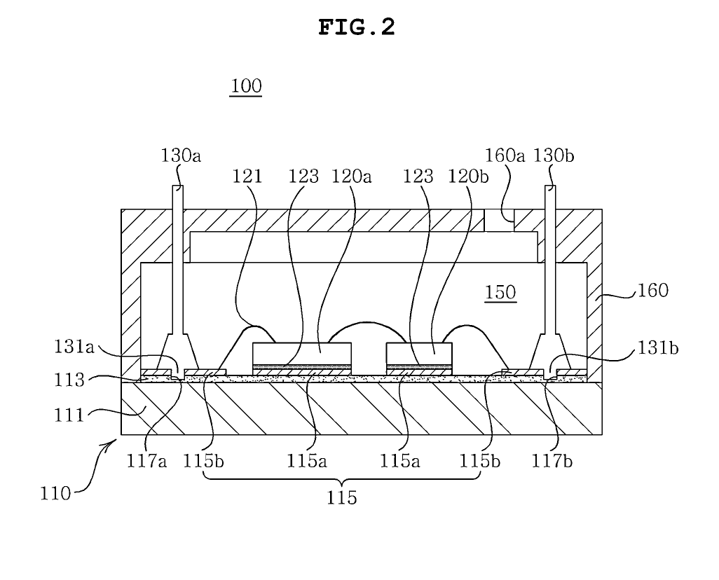

Further, as illustrated in FIG. 2, a surface of the one terminal of the external connection terminals 130a and 130b of the power module package 100 according to the preferred embodiment of the present invention may be formed with protrusions 131a and 131b.

This is to facilitate the arrangement of the external connection terminals 130a and 130b and prevent the external connection terminals 130a and 130b from separating in place during the welding process, when the external connection terminals 130a and 130b are bonded to the external connection pad 115b of the substrate 110.

In this case, insertion grooves 117a and 117b corresponding to the protrusions 131a and 131b may be formed on the substrate 110 and the insertion grooves 117a and 117b may be inserted to a predetermined depth in a thickness direction of the insulating layer 113 by penetrating through the external connection pad 115b, for example, as illustrated in FIG. 2, but are not particularly limited thereto.

As illustrated in FIG. 1, the power module package 100 according to the preferred embodiment of the present invention may further include a case 160 which is formed to cover one surface of the substrate 110, the semiconductor chips 120a and 120b, and a portion of the external connection terminals 130a and 130b and expose the other terminal of the external connection terminals 130a and 130b to the outside.

In this case, the case 160 may be formed with an open part 160a for injecting a molding material into the case 160.

Further, the power module package 100 according to the preferred embodiment of the present invention may further include a sealing member 150 which is formed within the case 160 to enclose one surface of the substrate 110, the semiconductor chips 120a and 120b, a portion of the external connection terminals 130a and 130b, and the wire 121 electrically connecting them.

In this case, as the sealing member 150, a silicon gel, an epoxy molding compound (EMC), and the like, may be used, but the preferred embodiment of the present invention is not limited thereto.

In addition, although not illustrated, the power module package 100 according to the present embodiment may further include a heat sink bonded to the other surface of the substrate 110, that is, the exposed portion of the metal plate 111.

The heat sink may include a plurality of radiating fins to radiate heat generated from the semiconductor chips 120a and 120b into the air.

Further, the heat sink is not particularly limited, but is made of a copper (Cu) material or a tin (Sn) material or formed by coating the copper (Cu) material or the tin (Sn) material. The reason is that the copper (Cu) material or the tin (Sn) material has excellent heat transferability and facilitates the bonding between the heat sink and a heat radiating substrate.

According to the preferred embodiments of the present invention, the external connection terminals can be directly bonded on the substrate by the welding to remove the necessity of the socket for connecting the external connection terminals, thereby saving the process costs.

Further, according to the preferred embodiments of the present invention, the process for attaching the separate member for electrically and mechanically the external connection terminals to the substrate on the substrate can be removed by directly bonding the external connection terminals on the substrate by the welding, thereby simplifying the process and shortening the process time.

Although the preferred embodiments of the present invention have been disclosed for illustrative purposes, they are for specifically explaining the present invention and thus a linear vibration motor according to the present invention are not limited thereto, but those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. A power module package, comprising:
a substrate having one surface formed with a circuit pattern including a chip mounting pad and an external connection pad and the other surface;
a semiconductor chip mounted on the chip mounting pad; and
an external connection terminal having one terminal and the other terminal, the one terminal being connected to the external connection pad and the other terminal protruding to the outside,
wherein the external connection pad and the external connection terminal are bonded to each other by welding.

2. The power module package as set forth in claim 1, wherein the welding is any one selected from ultrasonic welding, laser welding, and resistance welding.

3. The power module package as set forth in claim 1, wherein one terminal of the external connection terminal is formed with a protrusion and the substrate is formed with an insertion groove corresponding to the protrusion.

4. The power module package as set forth in claim 3, wherein the substrate includes:
a metal plate;
an insulating layer formed on the metal plate; and
a circuit pattern formed on the insulating layer and including a chip mounting pad and an external connection pad,
wherein the insertion groove is formed to a predetermined depth in a thickness direction of the insulating layer by penetrating through the external connection pad.

5. The power module package as set forth in claim 1, wherein the external connection terminal has a pin shape.

6. The power module package as set forth in claim 1, wherein the external connection terminal is formed so that a diameter of the one terminal is larger than that of the other terminal

7. The power module package as set forth in claim 1, wherein the external connection terminal has a diameter which decreases from the one terminal toward the other terminal

8. The power module package as set forth in claim 1, further comprising:
a case formed on the substrate and covering one surface of the substrate, a semiconductor chip, and a portion of the external connection terminal and exposing the other terminal of the external connection terminal to the outside.

9. The power module package as set forth in claim 8, further comprising:
a sealing member formed within the case to enclose one surface of the substrate, the semiconductor chip, and a portion of the external connection terminal.
